(19) United States
(12) Patent Application Publication
(10) Pub. No.: US 2026/0165165 A1
(43) Pub. Date: Jun. 11, 2026

(54) SEMICONDUCTOR PACKAGE AND METHOD OF FABRICATION

(71) Applicant: Infineon Technologies Americas Corp., El Segundo, CA (US)

(72) Inventors: Shunhe Xiong, Westford, MA (US); Grant Maloney, Ashburnham, MA (US)

(21) Appl. No.: 19/399,428

(22) Filed: Nov. 24, 2025

Related U.S. Application Data
(60) Provisional application No. 63/728,598, filed on Dec. 5, 2024.

(51) Int. Cl. H01L 23/498; H01L 23/00; H01L 23/055; H01L 23/15

(52) U.S. Cl. CPC H10W 70/65; H10W 70/635; H10W 70/692; H10W 76/153; H10W 90/724

(57) ABSTRACT

In accordance with an embodiment, a package for a flip-chip power semiconductor device includes: a base having a top surface and a bottom surface; a plurality of stacked conductive vias extending through the base from the top surface to the bottom surface; a plurality of solder pads on the top surface of the base, wherein at least one solder pad of the plurality of solder pads is coupled to a stacked conductive via of the plurality of stacked conductive vias, and the at least one solder pad is configured to be electrically connected to at least one solder bump of a semiconductor die; and a plurality of conductive pads on the bottom surface of the base, where at least one conductive pad of the plurality of conductive pads is electrically connected to the stacked conductive vias.

### CROSS-REFERENCE TO RELATED APPLICATIONS

This application claims the benefit of U.S. Provisional Application No. 63/728,598, filed on December 5, 2024, which application is hereby incorporated herein by reference.

### TECHNICAL FIELD

The present invention relates generally to a system and method for an electronic system, and, in particular embodiments, to a semiconductor package and method of fabrication.

### BACKGROUND

Power semiconductor devices are widely used in various electronic applications, including power conversion systems, motor drives, and switching power supplies. Traditional power semiconductor devices, such as silicon-based MOSFETs, typically employ wire bonding technology to establish electrical connections between the semiconductor device and the package. These devices generally have terminals located on opposite sides of the die, with one terminal on the bottom surface and other terminals on the top surface.

Recent advances in semiconductor technology have led to the development of wide bandgap semiconductor materials, such as gallium nitride (GaN), which offer superior electrical performance characteristics compared to traditional silicon-based devices. These newer semiconductor devices often utilize flip-chip configurations where all terminals are located on a single side of the die. This configuration presents unique packaging challenges, particularly for applications requiring hermetic sealing, low electrical resistance, high current handling capability, and operation at high frequencies. The packaging of flip-chip power semiconductor devices for demanding applications such as military and space environments requires specialized design considerations to achieve the desired electrical, thermal, and mechanical performance while maintaining reliability in harsh operating conditions.

### SUMMARY

In accordance with an embodiment, a package for a flip-chip power semiconductor device includes: a base having a top surface and a bottom surface; a plurality of stacked conductive vias extending through the base from the top surface to the bottom surface; a plurality of solder pads on the top surface of the base, wherein at least one solder pad of the plurality of solder pads is coupled to a stacked conductive via of the plurality of stacked conductive vias, and the at least one solder pad is configured to be electrically connected to at least one solder bump of a semiconductor die; and a plurality of conductive pads on the bottom surface of the base, where at least one conductive pad of the plurality of conductive pads is electrically connected to the stacked conductive vias.

In accordance with another embodiment, a packaged flip-chip semiconductor device, includes: a package body; a plurality of stacked conductive vias extending through the package body from a top surface of the package body to a bottom surface of the package body; a plurality of solder pads on the top surface of the package body electrically connected to the plurality of stacked conductive vias; a semiconductor die mounted on the top surface of the package body and electrically connected to the plurality of solder pads via solder bumps; and a lid attached to the top surface of the package body.

In accordance with a further embodiment, a method of manufacturing a hermetic package for a flip-chip semiconductor device includes: providing a base comprising one or more layers; forming a plurality of stacked conductive vias through the one or more layers of the base; attaching a flip-chip power semiconductor die to conductive traces on a top surface of the base via solder bumps, wherein the conductive traces are electrically connected to the plurality of stacked conductive vias; placing a lid over the flip-chip power semiconductor die; and sealing the lid to the base.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross-sectional view of a package assembly, according to aspects of the present disclosure;

FIG. 2A shows a top view of a package body with stacked conductive vias; FIG. 2B depicts a bottom view of the package body of FIG. 2A with conductive pads; and FIG. 2C illustrates a superimposed view of the package body showing top and bottom surfaces, according to aspects of the present disclosure;

FIG. 3 shows a pinout configuration of a flip-chip power semiconductor die, according to aspects of the present disclosure.

FIG. 4A depicts a cross-sectional view during a die attach process; and FIG. 4B illustrates a cross-sectional view showing lid positioning and sealing, according to aspects of the present disclosure; and

FIG. 5A shows a three-dimensional cutaway view of the package assembly of FIG. 1; and FIG. 5B depicts an exploded view of the package assembly of FIG. 1, according to aspects of the present disclosure.

Corresponding numerals and symbols in different figures generally refer to corresponding parts unless otherwise indicated. The figures are drawn to clearly illustrate the relevant aspects of the embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The making and using of the disclosed embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In accordance with various embodiments, a hermetic package for a flip-chip power semiconductor device may include a base with stacked conductive vias for low resistance current conduction. In some embodiments, the package may feature a solder pad design that connects multiple solder bumps to a single stacked conductive via, which may advantageously allow for balanced current flow and isolation distance. The bottom of the package may include shaped pads for easier customer use and compatibility with existing power device designs. In certain embodiments, highly conductive traces may be employed for low resistance. The package may further include a hermetically sealed cavity with a lid to protect the semiconductor die.

In some embodiments, the package may offer extremely low resistance compared to traditional power semiconductor packages. The package may be capable of handling high currents and operating at high frequencies.

Advantages of some embodiments include good thermal performance and reliability in harsh environments. The package design may advantageously allow for easier integration into existing systems. In some embodiments, the package may feature balanced current flow between terminals.

In particular embodiments, the base of the package may be made of a ceramic material such as aluminum nitride (AlN) using a high-temperature co-fired process. The conductive vias may be tungsten, and the highly conductive traces may be copper. The semiconductor die may be a gallium nitride (GaN) device in some implementations. These specific material choices and semiconductor types may provide particular advantages in terms of thermal management, electrical performance, and suitability for harsh environments.

Packaged semiconductor devices according to various embodiments may exhibit advantageous electrical performance characteristics compared to traditional power device packages. In some embodiments, package resistance values may be reduced by approximately one order of magnitude, from typical ranges of 10-20 milliohms down to 1-2 milliohms, which may accommodate the high-current, high-frequency operation characteristics of advanced semiconductor devices. This reduction in package resistance may enable the handling of substantial direct current levels, potentially ranging from 40 to 100 amperes, while maintaining efficient power conversion and minimizing joule heating within the package structure.

High-frequency operation capabilities may represent another area where hermetic flip-chip packages according to embodiments may provide advantages over traditional packaging approaches. These packages may exhibit switching frequencies exceeding 400 kilohertz and potentially extending into the megahertz range, which may be beneficial for switch-mode power supply applications and other power conversion systems where size and efficiency are considerations. The low inductance characteristics that may be achievable through flip-chip mounting and stacked conductive vias may contribute to reduced electrical ringing and voltage spikes during high-speed switching operations.

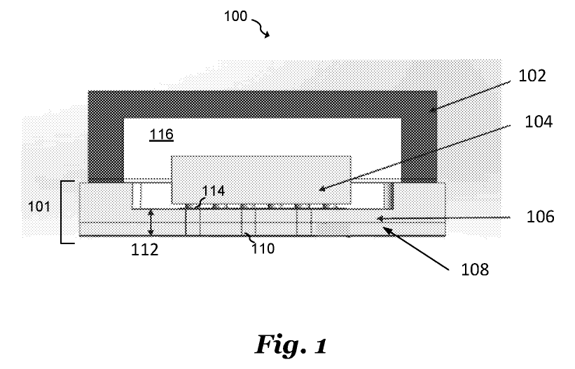

Referring to FIG. 1, a package assembly 100 provides a hermetic packaging solution for a flip-chip power semiconductor device. The package assembly 100 incorporates structural design elements and material compositions to achieve low electrical resistance, high current handling capabilities, and environmental protection for semiconductor components. The package assembly 100 includes a package body 101, a lid 102, a die 104, a cavity 116 that accommodates the semiconductor die 104, and various internal structural elements that work together to provide electrical connectivity and environmental protection.

The package body 101 forms the primary structural foundation of the package assembly 100 and houses the electrical interconnection elements for flip-chip mounting configurations. The package body 101 may be constructed from aluminum nitride (AlN) ceramic material, which provides thermal conductivity characteristics that facilitate heat dissipation from high-power semiconductor devices while maintaining electrical insulation properties between conductive pathways. The aluminum nitride material composition may offer thermal expansion coefficients that closely match those of gallium nitride semiconductor devices, thereby reducing thermomechanical stress during temperature cycling operations. The package body 101 includes a bottom package layer 106, a top package layer 108, and stacked conductive vias 110.

The bottom package layer 106 and top package layer 108 form a multilayer structure of the package body 101, with the base thickness 112 determined by the combined dimensions of these layers. In some embodiments, bottom package layer 106 and top package layer 108 is formed and bonded together using a High-Temperature Co-fired Ceramic (HTCC) process with aluminum nitride as the primary material. This process can allow for the integration of the conductive vias and traces within the ceramic structure, potentially resulting in a robust and thermally efficient package.

The stacked conductive vias 110 extend through the base thickness 112 from the top surface to the bottom surface of the package body 101, providing low-resistance electrical pathways for current conduction between the semiconductor die and external circuit connections. As shown in FIG. 1, the stacked conductive vias 110 maintain vertical alignment through the package layers, which may minimize electrical resistance compared to alternative configurations that utilize laterally offset or staggered via arrangements.

The stacked conductive vias 110 may be formed using a High-Temperature Co-fired Ceramic (HTCC) manufacturing process that enables precise control of via geometry and electrical characteristics. In this process, holes may be punched or drilled through the ceramic layers of the base, followed by filling with a paste mixture containing tungsten and ceramic materials along with organic binders. The entire structure may undergo a high-temperature firing process during which the organic binders are burned away and the ceramic and tungsten materials are sintered together to form the conductive pathway and to provide conductive vias 110 made of tungsten. The HTCC process may allow for the integration of the conductive vias within the aluminum nitride ceramic base structure, creating a robust package with thermal and electrical performance characteristics. This manufacturing approach may enable the achievement of very low package resistance values that may be beneficial for high-current, high-frequency applications.

The stacked configuration of the conductive vias 110 may provide electrical resistance values ranging from 1 to 2 milliohms, representing a reduction of approximately one order of magnitude compared to traditional wire-bonded power device packages. This low resistance characteristic enables the package assembly 100 to handle direct current levels ranging from 40 to 100 amperes while maintaining efficient power transfer and minimizing joule heating within the interconnection structure. The stacked conductive vias 110 may also contribute to inductance reduction, with total package inductance values of less than one nanohenry achievable compared to approximately four nanohenries typical of wire-bonded packages. In some cases, closely staggered vias with minimum lateral traces may serve as an alternative configuration to the stacked conductive vias 110, though such arrangements may result in increased electrical resistance due to the additional lateral conduction paths.

The cavity 116 within the package body 101 is defined by lid 102 and provides a recessed region that accommodates the die 104 and associated interconnection elements. The die 104 may include a flip-chip power semiconductor device that may comprise a gallium nitride (GaN) functional layer deposited on a silicon substrate for mechanical support and cost reduction. The gallium nitride material provides the active semiconductor functionality, while the silicon substrate offers structural stability and process compatibility with established semiconductor manufacturing techniques.

The die attach solder 114 provides both electrical and mechanical connections between the die 104 and the package body 101. The die attach solder 114 may include high-lead solder compositions that offer thermal and electrical conductivity characteristics while maintaining reliability under high-temperature operating conditions typical of military and space applications. The high-lead solder composition may provide melting point characteristics that enable reliable reflow processing while maintaining joint integrity during subsequent assembly operations and long-term service exposure. Alternatively, non-lead solder compositions may be used, for example, in commercial applications.

The lid 102 covers the cavity 116 and die 104 to form a hermetically sealed enclosure that protects the semiconductor components from environmental contamination. The lid 102 may be constructed from the same aluminum nitride material as the package body 101 to ensure thermal expansion compatibility and minimize thermomechanical stress during temperature cycling. The hermetic seal formed between the lid 102 and package body 101 may achieve low moisture ingress rates to provide environmental protection suitable for space applications where moisture outgassing and contamination control are considerations. The package assembly 100 may incorporate radiation-hardened design features that enable operation in high-radiation environments typical of military and space sectors, with semiconductor and packaging materials selected to maintain electrical performance characteristics under ionizing radiation exposure.

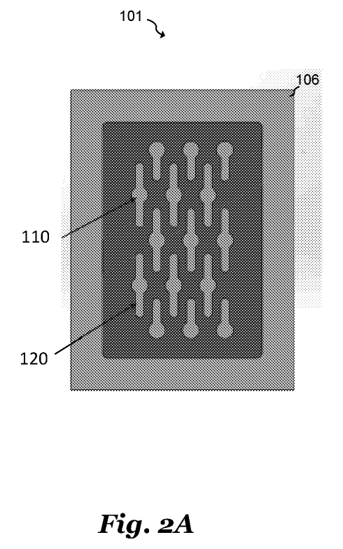

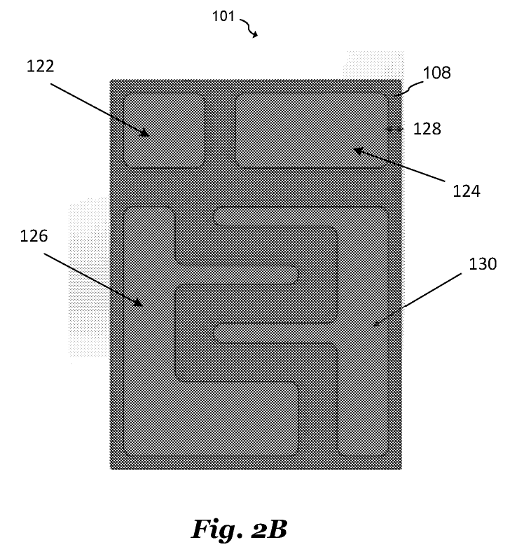

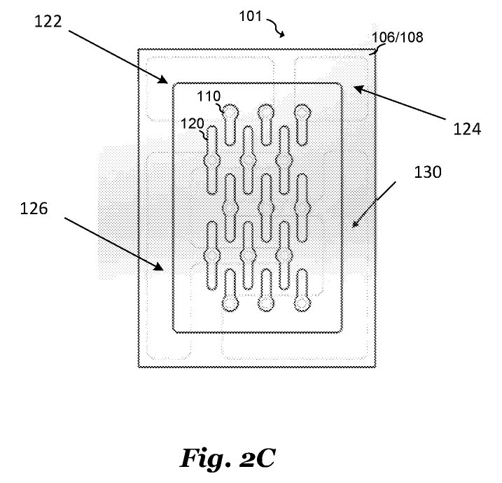

Referring to FIG. 2A, the top surface of the package body 101 incorporates a solder pad configuration that facilitates electrical connections between the die 104 and the stacked conductive vias 110. The top surface layout includes a plurality of solder pads 120 arranged in a pattern that accommodates the flip-chip mounting requirements of power semiconductor devices while maintaining electrical isolation between different circuit nodes. The solder pads 120 may be positioned within the cavity 116 region of the package body 101 and may be configured to receive solder bumps from the die 104 during flip-chip assembly operations. Each of the solder pads 120 may be electrically connected to one or more of the stacked conductive vias 110 through conductive trace pathways that extend across the top surface of the package body 101. The arrangement of the solder pads 120 may provide balanced current distribution between source and drain terminals of power semiconductor devices while maintaining isolation distances between different electrical nodes.

The solder pads 120 may be arranged in a pattern where each of the stacked conductive vias 110 connects to two of the solder pads 120 through a trace design that optimizes space utilization and maintains isolation distance between adjacent electrical connections. This two-pad via connection design may enable efficient use of the available surface area within the cavity 116 while providing adequate spacing between solder connection points to prevent electrical shorts during assembly operations. Alternatively, one or more stacked conducive vias 110 may be connected to a single solder pad 120 or to three or greater solder pads 120. The trace pathways connecting the solder pads 120 to the stacked conductive vias 110 may incorporate multiple metal layers including tungsten, nickel, copper, and gold, with each layer serving specific functions for electrical conductivity and reliability. The copper layer within the trace structure may provide low-resistance current paths that contribute to the overall package resistance values of 1 to 2 milliohms. The conductive traces may extend from individual solder pads 120 to centrally located connection points where the stacked conductive vias 110 provide vertical electrical pathways through the package body 101 to the bottom surface conductive pads.

The geometric arrangement of the solder pads 120 may accommodate the pinout configuration of semiconductor devices that incorporate source, drain, and gate terminals distributed across the die surface. Alternatively, other pinout configurations can be accommodated. The solder pads 120 may be configured to receive solder bumps from the die 104, with each solder bump providing both electrical and mechanical connections between the semiconductor die 104 and the package interconnection structure. The spacing and arrangement of the solder pads 120 may be designed to match the solder bump pattern of the die 104 while maintaining electrical isolation distances that prevent voltage breakdown between adjacent terminals during high-voltage operation.

Referring to FIG. 2B, the bottom surface of the package body 101 incorporates a conductive pad arrangement that provides electrical interface connections for mounting the package assembly 100 to external circuit boards. The bottom surface design facilitates customer integration while maintaining electrical isolation between different circuit nodes and providing mechanical stability during assembly operations. The conductive pad configuration may include multiple pad geometries and spacing arrangements that accommodate high-current power device applications while meeting electrical isolation standards. The bottom surface of the package body 101 includes conductive pads 122, 124, 126 and 130 arranged with respect to conductive pad pullback 128.

The conductive pad 124 provides a square connection point with rounded corners that may serve as a gate terminal interface for the semiconductor device. This pad geometry offers adequate surface area for solder joint formation while maintaining compact dimensions appropriate for low-current gate control signals. The conductive pad 124 may be positioned to align with corresponding solder pads 120 on the top surface through the stacked conductive vias 110, enabling electrical continuity from the die 104 to the external circuit board interface.

The conductive pad 122 incorporates a rectangular geometry that may function as a source sense terminal connection. This pad configuration enables Kelvin sensing capabilities that allow accurate voltage measurements at the semiconductor device terminals without interference from current-carrying path resistance. The conductive pad 122 may be electrically connected to the stacked conductive vias 110 within the package body 101, providing low-resistance connections to corresponding solder pads 120 on the top surface.

The conductive pads 126 and 130 feature an F-shaped geometry that maximizes electrical performance for high-current applications while maintaining a compact package footprint. This F-shaped configuration provides increased surface area compared to rectangular pad designs, enabling improved current distribution and reduced electrical resistance for source or drain terminal connections. The conductive pad 126 may be positioned symmetrically with respect to the conductive pad 130 to ensure balanced current flow characteristics between source and drain terminals of power semiconductor devices. The F-shaped geometry of conductive pads 126 and 130 may accommodate multiple solder connection points while maintaining adequate spacing from adjacent conductive pads to prevent electrical shorts during assembly operations, as well as compatibility with existing power device board layouts.

The conductive pad pullback 128 represents a controlled distance between the edges of the conductive pads and the perimeter of the package body 101. In one example, this pullback distance may be approximately 7 mils, providing a balance between stress reduction and maintenance of adequate contact area for reliable electrical connections. However, other pullback distances may be used depending on the particular embodiment and its specifications. The conductive pad pullback 128 may prevent solder from flowing to the edge of the device, which reduces mechanical stress concentrations that could lead to cracking or delamination during thermal cycling operations. The pullback design may also enable visual inspection of solder joint quality during assembly operations, as the solder connections remain visible rather than extending to the package edge where inspection would be difficult.

In one example, the spacing between adjacent conductive pads may be maintained at approximately 28 mils to provide electrical isolation between different circuit nodes. This spacing dimension may enable voltage isolation capabilities ranging from 100 volts to 200 volts according to European electrical safety standards, accommodating the operating voltage requirements of power semiconductor devices. The consistent spacing between the conductive pad 122, the conductive pad 124, the conductive pad 126, and the conductive pad 130 may prevent voltage breakdown between terminals during high-voltage operation while maintaining compact package dimensions. Alternatively, other spacings may be used depending on the particular embodiment and its specifications. The isolation distance may be selected based on the dielectric strength characteristics of the aluminum nitride package material and the operating environment conditions typical of military and space applications where the package assembly 100 may be deployed.

Referring to FIG. 2C, the electrical connectivity structure of the package body 101 demonstrates the relationship between the top surface solder pads 120 and the bottom surface conductive pads 122, 124, 126 and 130 through the stacked conductive vias 110. The alignment and visual representation shown in FIG. 2C illustrates how the conductive pads 122, 124, 126, and 130 are positioned with respect to the stacked conductive vias 110 within the package body 101. The conductive pads 122, 124, 126, and 130 are shown in dashed lines to indicate their location on the bottom surface of the package body 101, while the solid lines represent the top surface features including the solder pads 120 and the stacked conductive vias 110. This superimposed view shows alignment between the top and bottom surface elements, where each of the conductive pads 122, 124, 126, and 130 corresponds to specific groupings of the stacked conductive vias 110 that provide electrical continuity through the package structure.

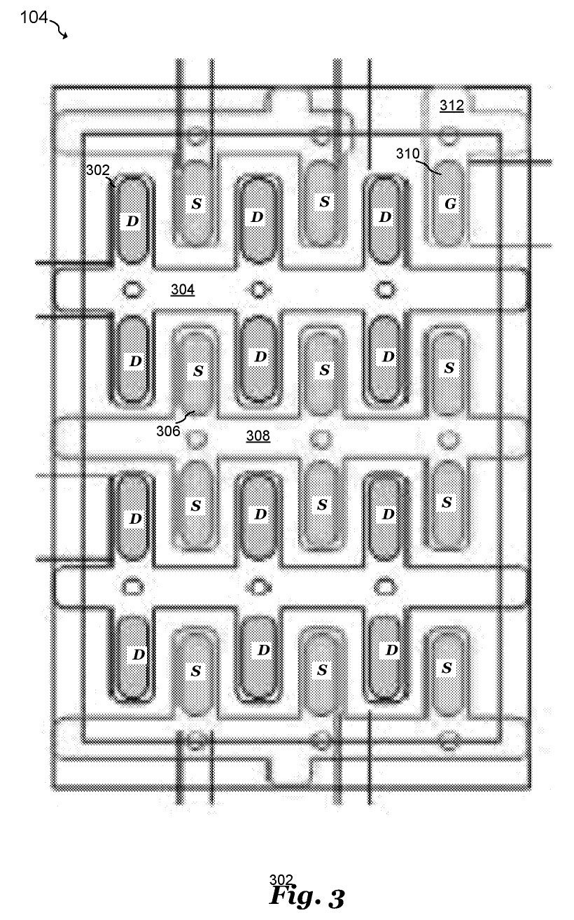

FIG. 3 illustrates a surface of semiconductor die 104 that incorporates a flip-chip semiconductor configuration that enables direct electrical connections between the semiconductor die 104 and the solder pads 120 on the top surface of the package body 101. As shown, the surface of die 104 includes drain solder bumps 302, drain conductive traces 304, source solder bumps 306, source conductive traces 308, a gate solder bump 310, and a gate conductive trace 312.

The surface of die 104 incorporates solder bumps and conductive traces that provide electrical connections between the semiconductor die 104 and the package interconnection structure. Solder bumps 302, 206 and 310 may be formed using high-lead solder compositions that provide reliable electrical and mechanical connections during flip-chip assembly operations, though non-lead solder compositions may alternatively be used. Each solder bump may align with corresponding solder pads 120 on the package body 101, enabling current flow through the stacked conductive vias 110 to the bottom surface conductive pads. The conductive traces may be formed using metallization layers deposited on the die 104 surface during semiconductor fabrication processes and may incorporate multiple metal layers to minimize electrical resistance and accommodate the current densities associated with power semiconductor operation.

Drain solder bumps 302 and drain conductive traces 304 provide electrical pathways for the drain terminal of the power semiconductor device. Multiple drain solder bumps 302 may be distributed across the surface of the die 104 in a pattern that accommodates high current flow requirements while maintaining electrical isolation from other circuit nodes. The drain conductive traces 304 connect the drain solder bumps 302 to the active regions of the die 104, with geometric layouts designed to provide uniform current distribution across the active semiconductor regions while maintaining adequate spacing from other electrical nodes to prevent voltage breakdown during high-voltage operation. The arrangement may accommodate current handling capabilities ranging from 40 to 100 amperes DC, with even higher pulse current levels possible during transient operating conditions.

Source solder bumps 306 and source conductive traces 308 establish electrical connections for the source terminal of the power semiconductor device. The source solder bumps 306 may be positioned between the drain solder bumps 302 in a pattern that provides balanced current flow characteristics and maintains electrical isolation between source and drain terminals. The source conductive traces 308 connect the source solder bumps 306 to the active semiconductor regions within the die 104, with metallization structures that may incorporate similar multi-layer compositions as the drain conductive traces to ensure consistent electrical performance. The arrangement of drain solder bumps 302 and source solder bumps 306 may enable symmetric current distribution that minimizes electrical resistance differences between current paths and supports current handling capabilities ranging from 40 to 100 amperes DC, with even higher pulse current levels possible during transient operating conditions.

The gate solder bump 310 and gate conductive trace 312 provide a control terminal connection for the power semiconductor device. The gate solder bump 310 may be positioned in a location that maintains electrical isolation from the high-current source and drain terminals while providing accessible connection to the package interconnection structure. The gate conductive trace 312 establishes electrical connection between the gate solder bump 310 and a gate electrode structure within the die 104. The gate solder bump 310 may be formed using the same solder composition as the source and drain solder bumps, though the current handling requirements may be lower due to the control function of the gate terminal. The metallization structure of the gate conductive trace 312 may incorporate similar fabrication techniques as the source and drain traces, with positioning arranged to minimize parasitic capacitance and inductance effects that could impact the high frequency switching performance of the power semiconductor device.

The solder pads 120 on the top surface of the package body 101 may be arranged in a pattern that provides balanced current flow between the source and drain terminals while accommodating the gate terminal connection and maintaining electrical isolation between all circuit nodes. Each drain solder bump 302 and source solder bump 306 may align with specific solder pads 120 on the package body 101 to provide low-resistance current paths through the stacked conductive vias 110 to the bottom surface F-shaped conductive pads 126 and 130, while the gate solder bump 310 may align with a corresponding solder pad 120 that connects through the stacked conductive vias 110 to conductive pad 124 on the bottom surface of the package body 101.

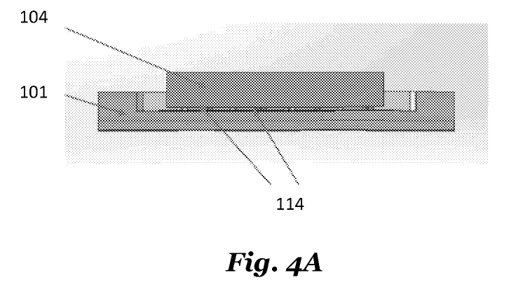

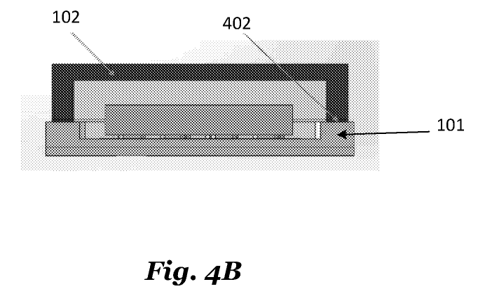

Referring to FIG. 4A, the die attachment process represents a manufacturing step where the die 104 is mounted to the package body 101 using the die attach solder 114. The die attachment process establishes both electrical and mechanical connections between the semiconductor die 104 and the package interconnection structure through controlled solder reflow operations. During this process, the die 104 is positioned on the top surface of the package body 101 such that solder bumps on the die 104 align with corresponding solder pads 120 on the package body 101. Heat is applied to the assembly to enable solder flow between the solder bumps of the die 104 and the solder pads 120 of the top surface of the package body 101, creating permanent electrical and mechanical bonds. The die attachment process may be performed in controlled atmosphere environments to prevent oxidation of the solder joints and ensure reliable electrical connections throughout the operational lifetime of the package assembly 100.

The die attach solder 114 may comprise high-lead solder compositions that provide electrical and thermal conductivity characteristics while maintaining reliability under high-temperature operating conditions. The electrical conductivity of high-lead solder enables low-resistance connections that contribute to the overall package resistance values of 1 to 2 milliohms, while the thermal conductivity characteristics facilitate heat transfer from the die 104 to the package body 101 during high-power operation. Alternatively, non-lead solder compositions may be used.

The die attachment process may utilize controlled heating profiles that bring the assembly temperature above the melting point of the die attach solder 114 while avoiding thermal damage to the semiconductor device or package materials. Cooling rates may be controlled to prevent thermal shock and minimize residual stress within the solder joints. The die attachment process may be performed using convection reflow ovens, infrared heating systems, or localized heating techniques depending on the specific assembly requirements and production volume considerations. Flux materials may be applied to the solder pads 120 prior to die placement to remove oxide films and promote solder wetting during the reflow process.

The mechanical alignment during the die attachment process ensures that each solder bump on the die 104 makes contact with the corresponding solder pad 120 on the package body 101. Precision placement equipment may be used to achieve alignment to achieve reliable electrical connections while preventing solder bridging between adjacent pads. The die 104 may be held in position during the reflow process using vacuum fixtures or mechanical restraints that maintain alignment while allowing for thermal expansion of the materials. Following completion of the die attachment process, the assembly may undergo inspection procedures including X-ray imaging to verify solder joint quality and detect potential defects such as voids or incomplete wetting that could affect electrical performance or long-term reliability.

Referring to FIG. 4B, the lid sealing process represents a manufacturing step that establishes a hermetic enclosure around the die 104 within the package assembly 100. The lid sealing process creates environmental protection for the semiconductor device by forming a controlled atmosphere barrier that prevents moisture ingress and contamination during long-term operation. During this process, the lid 102 is positioned over the cavity 116 containing the die 104, and a lid seal solder 402 is applied between the lid 102 and the package body 101 to create a permanent hermetic bond. The lid sealing process may be performed using controlled heating profiles that bring the assembly temperature above the melting point of the lid seal solder 402 while maintaining the integrity of previously formed solder joints between the die 104 and the solder pads 120. The hermetic seal formed through this process enables the package assembly 100 to meet environmental protection standards for military and space applications where moisture control and atmospheric isolation are considerations.

The lid seal solder 402 provides the hermetic sealing interface between the lid 102 and the package body 101, creating a moisture-resistant barrier around the die 104. The lid seal solder 402 may comprise a gold-tin alloy with a composition of 80% gold and 20% tin, which provides melting point characteristics that enable reliable reflow processing while maintaining joint integrity during subsequent thermal cycling operations. This gold-tin alloy composition offers corrosion resistance properties that maintain hermetic seal integrity over extended operational periods, with the gold content providing oxidation resistance and the tin content contributing to wetting characteristics during the soldering process. The lid seal solder 402 may be supplied as a preformed frame or gasket that matches the perimeter geometry of the package body 101, enabling consistent solder volume distribution around the sealing interface. The gold-tin alloy composition provides mechanical properties that accommodate thermal expansion differences between the lid 102 and package body 101 during temperature cycling while maintaining seal integrity.

The hermetic sealing performance of the package assembly 100 may achieve moisture ingress rates of 10⁻¹⁰ cubic liters per hour, providing environmental protection suitable for space applications where moisture outgassing and contamination control are considerations. This hermetic seal performance level prevents atmospheric moisture from entering the cavity 116 and protects the die 104 from corrosion and electrical degradation that could occur due to moisture exposure. The sealing process may be performed in controlled atmosphere environments using nitrogen or forming gas to displace atmospheric moisture and oxygen from the cavity 116 prior to lid attachment. Temperature profiles during the lid sealing process may be controlled to ensure complete melting and flow of the lid seal solder 402 while avoiding thermal damage to the die 104 or degradation of the die attach solder 114 connections.

The lid 102 may be constructed from the same aluminum nitride material as the package body 101 to ensure thermal expansion compatibility and minimize thermomechanical stress during temperature cycling operations. This material matching prevents differential thermal expansion that could create stress concentrations at the lid seal solder 402 interface and potentially compromise hermetic seal integrity over repeated thermal cycles.

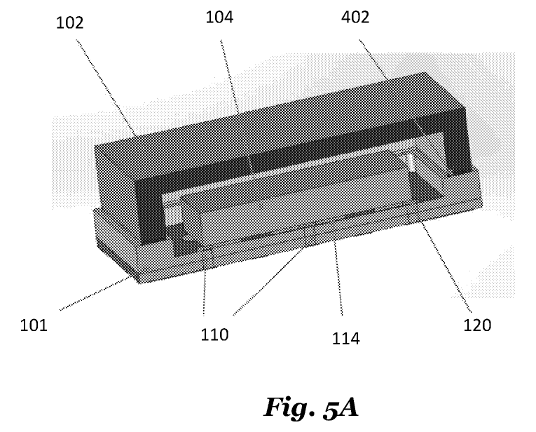

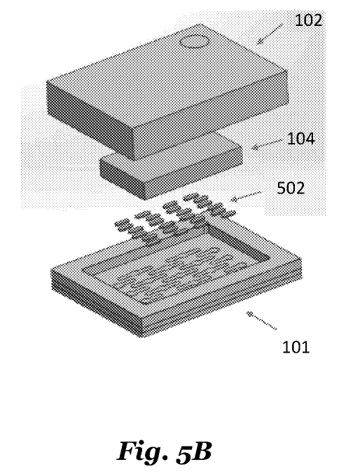

Referring to FIG. 5A, the package assembly 100 provides a three-dimensional cutaway view that demonstrates the complete structural integration of all components within the hermetic packaging configuration. The three-dimensional perspective illustrates the spatial relationships between the package body 101, the lid 102, the die 104, the stacked conductive vias 110, the die attach solder 114, the solder pads 120, and the lid seal solder 402. The package body 101 forms the structural foundation that houses the electrical interconnection pathways and provides mechanical support for the semiconductor device mounting configuration. The cavity 116 within the package body 101 provides a recessed region that accommodates the die 104 and associated interconnection elements while enabling the formation of a hermetic seal with the lid 102.

The stacked conductive vias 110 extend through the base thickness 112 and provide low-resistance electrical pathways that enable current conduction between the die 104 and external circuit connections. The vertical alignment of the stacked conductive vias 110 through the package layers minimizes electrical resistance compared to alternative configurations that utilize laterally offset via arrangements. The solder pads 120 on the top surface of the package body 101 incorporate multi-layer metallization structures that provide electrical connections between the die 104 and the stacked conductive vias 110.

FIG. 5B illustrates an exploded view of package assembly 100 that demonstrates the individual components and their assembly relationships within the hermetic packaging configuration. The exploded view illustrates the spatial separation between the package body 101, the lid 102, the die 104, and the die attach solder 114, enabling visualization of how these components integrate during the manufacturing process. The exploded perspective reveals the cavity 116 within the package body 101 that accommodates the die 104 and associated interconnection elements. The package assembly 100 includes the package body 101, the lid 102, the die 104, the die attach solder 114, and solder bumps 502.

Embodiments of the present invention are summarized here. Other embodiments can also be understood from the entirety of the specification and the claims filed herein.

Example 1. A package for a flip-chip power semiconductor device includes: a base having a top surface and a bottom surface; a plurality of stacked conductive vias extending through the base from the top surface to the bottom surface; a plurality of solder pads on the top surface of the base, where at least one solder pad of the plurality of solder pads is coupled to a stacked conductive via of the plurality of stacked conductive vias, and the at least one solder pad is configured to be electrically connected to at least one solder bump of a semiconductor die; and a plurality of conductive pads on the bottom surface of the base, where at least one conductive pad of the plurality of conductive pads is electrically connected to the stacked conductive vias.

Example 2. The package of example 1, further including the semiconductor die mounted on the top surface of the base and electrically connected to the at least one solder pad.

Example 3. The package of example 1 or example 2, where the semiconductor die includes a gallium nitride (GaN) device.

Example 4. The package of any one of examples 1-3, further including a lid attached to the top surface of the base.

Example 5. The package of example 4, where the lid and the base form a hermetically sealed cavity enclosing the semiconductor die.

Example 6. The package of any one of examples 1-5, where the base includes a ceramic material.

Example 7. The package of example 6, where the ceramic material is aluminum nitride.

Example 8. The package of any one of examples 1-7, where the plurality of stacked conductive vias include tungsten.

Example 9. The package of any one of examples 1-8, further including conductive traces on the top surface of the base connecting the solder pads to the stacked conductive vias.

Example 10. The package of example 9, where the conductive traces include copper.

Example 11. The package of any one of examples 1-10, where the at least one conductive pad of the plurality of conductive pads includes an F-shaped pad.

Example 12. The package of any one of examples 1-11, where the package has a resistance of less than 2 milliohms.

Example 13. The package of any one of examples 1-12, where the package is configured to handle currents of at least 40 amps DC_prd_.

Example 14. The package of any one of examples 1-13, where the package is configured to operate at frequencies of at least 400 kHz.

Example 15. The package of any one of examples 1-14, where the solder pads on the top surface are arranged in a pattern that provides balanced current flow between source and drain terminals of a power semiconductor device.

Example 16. The package of any one of examples 1-15, where the stacked conductive via is connected to at least two solder pads of the plurality of solder pads.

Example 17. The package of any one of examples 1-16, where the base includes a plurality of layers.

Example 18. A packaged flip-chip semiconductor device, including: a package body; a plurality of stacked conductive vias extending through the package body from a top surface of the package body to a bottom surface of the package body; a plurality of solder pads on the top surface of the package body electrically connected to the plurality of stacked conductive vias; a semiconductor die mounted on the top surface of the package body and electrically connected to the plurality of solder pads via solder bumps; and a lid attached to the top surface of the package body.

Example 19. The packaged flip-chip semiconductor device of example 18, where the lid and the package body form a hermetically sealed cavity enclosing the semiconductor die.

Example 20. A method of manufacturing a hermetic package for a flip-chip semiconductor device, the method including: providing a base including one or more layers; forming a plurality of stacked conductive vias through the one or more layers of the base; attaching a flip-chip power semiconductor die to conductive traces on a top surface of the base via solder bumps, where the conductive traces are electrically connected to the plurality of stacked conductive vias; placing a lid over the flip-chip power semiconductor die; and sealing the lid to the base.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, embodiments described herein pertain to a package for a GaN device. In alternative embodiments, the semiconductor package may be used to accommodate other devices besides a GaN device with the particular solder pad and conductive pad configurations shown and described herein. Other devices may have different functions, different solder pad configurations, different conductive pad configurations, and a different number of electrical connections depending on the particular embodiment and its specifications. Moreover, embodiments packages may also house non-GaN devices and or devices having non-silicon substrates. It is therefore intended that the appended claims encompass any such modifications or embodiments.

What is claimed is:

1. A package for a flip-chip power semiconductor device, comprising:
a base having a top surface and a bottom surface;
a plurality of stacked conductive vias extending through the base from the top surface to the bottom surface;
a plurality of solder pads on the top surface of the base, wherein at least one solder pad of the plurality of solder pads is coupled to a stacked conductive via of the plurality of stacked conductive vias, and the at least one solder pad is configured to be electrically connected to at least one solder bump of a semiconductor die; and
a plurality of conductive pads on the bottom surface of the base, where at least one conductive pad of the plurality of conductive pads is electrically connected to the stacked conductive vias.

2. The package of claim 1, further comprising the semiconductor die mounted on the top surface of the base and electrically connected to the at least one solder pad.

3. The package of claim 2, wherein the semiconductor die comprises a gallium nitride (GaN) device.

4. The package of claim 2, further comprising a lid attached to the top surface of the base.

5. The package of claim 4, wherein the lid and the base form a hermetically sealed cavity enclosing the semiconductor die.

6. The package of claim 1, wherein the base comprises a ceramic material.

7. The package of claim 6, wherein the ceramic material is aluminum nitride.

8. The package of claim 1, wherein the plurality of stacked conductive vias comprise tungsten.

9. The package of claim 1, further comprising conductive traces on the top surface of the base connecting the solder pads to the stacked conductive vias.

10. The package of claim 9, wherein the conductive traces comprise copper.

11. The package of claim 1, wherein the at least one conductive pad of the plurality of conductive pads comprises an F-shaped pad.

12. The package of claim 1, wherein the package has a resistance of less than 2 milliohms.

13. The package of claim 1, wherein the package is configured to handle currents of at least 40 amps DC.

14. The package of claim 1, wherein the package is configured to operate at frequencies of at least 400 kHz.

15. The package of claim 1, wherein the solder pads on the top surface are arranged in a pattern that provides balanced current flow between source and drain terminals of a power semiconductor device.

16. The package of claim 1, wherein the stacked conductive via is connected to at least two solder pads of the plurality of solder pads.

17. The package of claim 1, wherein the base comprises a plurality of layers.

18. A packaged flip-chip semiconductor device, comprising:
a package body;
a plurality of stacked conductive vias extending through the package body from a top surface of the package body to a bottom surface of the package body;
a plurality of solder pads on the top surface of the package body electrically connected to the plurality of stacked conductive vias;
a semiconductor die mounted on the top surface of the package body and electrically connected to the plurality of solder pads via solder bumps; and
a lid attached to the top surface of the package body.

19. The packaged flip-chip semiconductor device of claim 18, wherein the lid and the package body form a hermetically sealed cavity enclosing the semiconductor die.

20. A method of manufacturing a hermetic package for a flip-chip semiconductor device, the method comprising:
providing a base comprising one or more layers;
forming a plurality of stacked conductive vias through the one or more layers of the base;
attaching a flip-chip power semiconductor die to conductive traces on a top surface of the base via solder bumps, wherein the conductive traces are electrically connected to the plurality of stacked conductive vias;
placing a lid over the flip-chip power semiconductor die; and
sealing the lid to the base.
